(19) United States
(12) Patent Application Publication
(10) Pub. No.: US 2026/0324342 A1
(43) Pub. Date: Oct. 15, 2026

(54) HIGH-PRESSURE SUBSTRATE PROCESSING APPARATUS

(71) Applicant: HPSP Co., Ltd., Hwaseong-si, Gyeonggi-do (KR)

(72) Inventor: Yeonchul KIM, Hwaseong-si, Gyeonggi-do (KR)

(21) Appl. No.: 19/486,154

(22) PCT Filed: May 17, 2024
(86) PCT No.: PCT/KR2024/095820

§ 371 Date: Nov. 20, 2025

(30) Foreign Application Priority Data
May 22, 2023 (KR) 10-2023-0065805

(51) Int. Cl. H10P 72/00

(52) U.S. Cl. CPC H10P 72/0434; H10P 72/0606

(57) ABSTRACT

The present invention provides a high-pressure substrate processing apparatus, comprising: an inner chamber formed to accommodate a substrate to be processed and a reaction gas supplied at a first pressure higher than atmospheric pressure; an outer chamber that is configured to accommodate a protection gas supplied at a second pressure set in relation to the first pressure, and includes an outer housing for accommodating the inner chamber, and an outer door formed to be movable between a closed state for closing the outer housing and an opened state for opening the outer housing: a fastening module including a support protrusion installed on the outer housing, and a locking protrusion installed on the outer door and positioned to correspond to the support protrusion by means of relative rotation with respect to the support protrusion in the closed state; a door moving module configured to move the outer door between the closed state and the opened state; and a control module that calculates a gap section in which the locking protrusion corresponding to the support protrusion can move between the outer housing and the support protrusion, and controls the door moving module to move the locking protrusion to a selected position within the calculated gap section.

### TECHNICAL FIELD

The present disclosure relates to a processing apparatus used to process a substrate in a high-pressure environment.

### BACKGROUND ART

Generally, during the semiconductor device manufacturing process, various types of processing are performed on a semiconductor substrate. Examples of the processing include oxidation, nitridation, deposition, ion implantation, etc. A hydrogen or deuterium heat treatment process is also used to improve the interface characteristics of the semiconductor device.

The gas used to process the substrate is supplied to the chamber at high pressure and acts on the semiconductor substrate. To maintain the chamber at high pressure, the housing of the chamber should be reliably closed by a door.

To this end, a fastening structure is adopted in which parts of the housing and the door are aligned with each other, with one supporting the other. When the door sags to one side due to the repeatedly applied high pressure, problems may arise during the fastening and unfastening process between the housing and the door. For example, particles may be generated due to an abrasion between protrusions during the fastening and unfastening process.

The above-described background art is technical information retained by the inventor to derive the embodiments of the present disclosure or acquired by the inventor while deriving the present disclosure, and thus should not be construed as art that was publicly known prior to the filing date of the present disclosure.

### DISCLOSURE

### Technical Problem

The present disclosure is to provide a high-pressure substrate processing apparatus capable of preventing particles from being generated during a fastening and unfastening process of a door while reliably maintaining a high pressure within a chamber.

### Technical Solution

According to an aspect of the present disclosure, a high-pressure substrate processing apparatus includes: an inner chamber configured to accommodate a substrate to be processed and a reaction gas supplied at a first pressure higher than atmospheric pressure; an outer chamber including an outer housing for accommodating the inner chamber and an outer door formed to be movable between a closed state in which the outer housing is closed and an opened state in which the outer housing is opened, and configured to accommodate a protection gas supplied at a second pressure set in relation to the first pressure: a fastening module including a support protrusion installed on the outer housing and a locking protrusion that is installed on the outer door and is positioned to correspond to the support protrusion by relative rotation with respect to the support protrusion in the closed state; a door moving module configured to move the outer door between the closed state and the opened state; and a control module configured to calculate a gap section that is a section in which the locking protrusion corresponding to the support protrusion is movable between the outer housing and the support protrusion, and control the door moving module to move the locking protrusion to a selected position within the calculated gap section.

The locking protrusion may further rotate relative to the support protrusion after being moved to the selected position.

The control module may calculate at least one of a lowest point and a highest point of the gap section, and set, as the selected position, one of the lowest point, the highest point, and a position therebetween.

The control module may calculate the gap section based on operating information of the door moving module.

The door moving module may include a motor that generates power, and the operating information may include a torque value of the motor.

The control module may set, as the lowest point, a point at which the change in the torque value exceeds a reference during downward movement of the outer door, set, as the highest point, a point at which the change in the torque value exceeds the reference during upward movement of the outer door, and set a section between the lowest point and the highest point as the gap section.

According to another aspect of the present disclosure, a high-pressure substrate processing apparatus includes: a chamber including a housing configured to accommodate a substrate to be processed and a process gas supplied at a pressure higher than atmospheric pressure, and a door configured to move vertically between a closed state in which the housing is closed and an opened state in which the housing is opened; a fastening module including a support protrusion that is installed on the housing and a locking protrusion that is installed on the door and is positioned to correspond to the support protrusion at an initial level in the closed state by relative rotation with respect to the support protrusion; a door elevating module configured to vertically move the door between the closed state and the opened state; and a control module configured to control the door elevating module so that the locking protrusion corresponding to the support protrusion moves vertically to an adjusted level different from the initial level according to a processing step for the substrate to be processed.

The control module may calculate at least one of a lowest point and a highest point within a vertical movable range while the locking protrusion is positioned to correspond to the support protrusion, and the adjustment level may be set relative to at least one of the lowest point and the highest point.

The adjustment level may be set to the lowest point before processing the substrate to be processed.

The adjustment level may be set to a position between the lowest point and the highest point during a transition between the closed state and the opened state.

The control module may control the door elevating module to lower the door to the opened state when the locking protrusion rotates relative to the support protrusion after moving the locking protrusion to the adjustment level.

The control module may calculate at least one of the lowest point and the highest point based on operating information of the door elevating module.

The process gas may include a reaction gas containing an active gas and a protection gas containing an inert gas, the housing may include an inner housing configured to accommodate the substrate to be processed and the reaction gas, and an outer housing accommodating the inner housing and coupled to the inner housing to form a closed space for accommodating the protection gas and the inner housing, and the door may be configured to close the inner housing.

### ADVANTAGEOUS EFFECTS

According to the high-pressure substrate processing apparatus of the present disclosure configured as described above, the door moving module is controlled so that the locking protrusion of the fastening module, which fastens the outer housing and the outer door, moves to the selected position within the gap section between the outer housing and the support protrusion of the fastening module, so it is possible for the fastening module to prevent the particles from being generated due to the abrasion between the locking protrusion and the support protrusion during the fastening and unfastening process of the outer door while reliably maintaining the high pressure within the outer chamber.

### BRIEF DESCRIPTION OF THE DRAWINGS

FIG. 1 is a conceptual diagram of a high-pressure substrate processing apparatus 100 according to an embodiment of the present disclosure.

FIG. 2 is an exploded perspective view illustrating an opened state in which an outer door 125 opens an outer housing 121, in the high-pressure substrate processing apparatus 100 of FIG. 1.

FIG. 3 is a partial cross-sectional view showing a closed state in which the outer door 125 closes the outer housing 121, in the high-pressure substrate processing apparatus 100 of FIG. 2.

FIG. 4 is a block diagram illustrating a control configuration of the high-pressure substrate processing apparatus 100 of FIG. 1.

FIG. 5 is a flowchart for describing an operation of the high-pressure substrate processing apparatus 100 according to another embodiment of the present disclosure.

FIG. 6 is a flowchart for describing in detail one step (S5) of FIG. 5.

FIG. 7 is a flowchart for describing in detail one step (S7) of FIG. 5.

### BEST MODE

Hereinafter, exemplary embodiments of the present disclosure will be described in detail with reference to the accompanying drawings.

The present disclosure is not limited to exemplary embodiments set forth herein, but may be modified in various different forms. However, the present embodiment is provided solely to ensure that the disclosure of the present disclosure is complete and to fully inform those skilled in the art of the scope of the invention. Therefore, the present disclosure is not limited to the embodiments disclosed below, but should be understood to encompass all modifications, equivalents, and substitutions within the teachings and scope of the present disclosure, including substitutions or additions of components of one embodiment with those of another.

It should be understood that the accompanying drawings are provided only in order to allow embodiments disclosed in the present specification to be easily understood, and the teachings disclosed in the present specification are not limited by the accompanying drawings, but includes all the modifications, equivalents, and substitutions included in the teachings and the scope of the present disclosure. In the drawings, components may be exaggerated in size or thickness for ease of understanding, but this should not be construed as limiting the scope of protection of the present disclosure.

Terms used in the present specification are used only in order to describe specific implementation examples or embodiments rather than limiting the present disclosure. Singular expressions are intended to include plural expressions unless the context clearly indicates otherwise. In the specification, terms such as “~comprising,” or “~consisting of” are intended to specify the presence of stated features, numbers, steps, operations, components, parts, or combinations thereof described in the specification. That is, it should be understood that terms such as “~including” or “~consisting of” in the specification do not preclude the existence or addition possibility of one or more other features or numbers, steps, operations, components, parts, or combinations thereof.

Terms including ordinal numbers such as “first”, “second”, etc., may be used to describe various components, but the components are not to be construed as being limited to the terms. The terms are used to distinguish one component from another component.

It is to be understood that when one element is referred to as being “connected to” or “coupled to” another element, it may be connected directly to or coupled directly to another element or be connected to or coupled to another element, having the other element intervening therebetween. On the other hand, it should be understood that when one element is referred to as being “connected directly to” or “coupled directly to” another element, it may be connected to or coupled to another element without the other element interposed therebetween.

When a component is referred to as being “above” or “below” another component, it should be understood that it is not only positioned directly above that other component, but also that other components may be present in between.

Unless indicated otherwise, it is to be understood that all the terms used in the specification including technical and scientific terms have the same meaning as those that are generally understood by those who skilled in the art. Terms generally used and defined by a dictionary should be interpreted as having the same meanings as meanings within a context of the related art and should not be interpreted as having ideal or excessively formal meanings unless being clearly defined otherwise in the present specification.

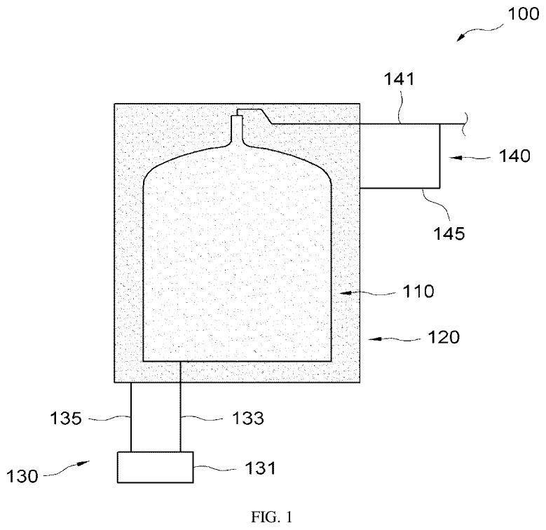

FIG. 1 is a conceptual diagram of a high-pressure substrate processing apparatus 100 according to an embodiment of the present disclosure.

Referring to this drawing, a high-pressure substrate processing apparatus 100 may include an inner chamber 110, an outer chamber 120, a gas supply module 130, and a gas exhaust module 140.

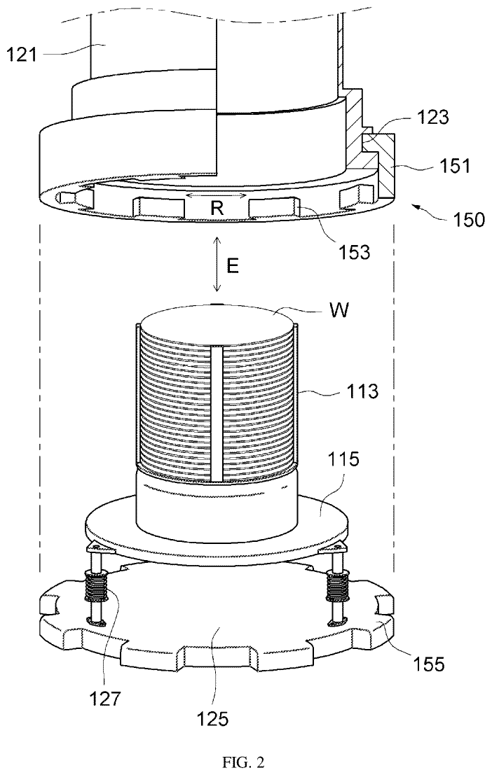

The inner chamber 110 forms a processing space that accommodates a substrate to be processed. The inner chamber 110 may be manufactured from a non-metallic material, such as quartz, to reduce contamination in a high-temperature and high-pressure operating environment. Depending on an operation of a heater (not illustrated) arranged on an outer side of the inner chamber 110, the temperature of the inner chamber 110 may reach several hundred to a thousand °C. The substrate may be, for example, a semiconductor substrate W (see FIG. 2) loaded onto a holder. The holder may be a wafer boat 113 (see FIG. 2) capable of loading a substrate W to be processed in multiple layers. The substrate is not limited to the wafer, and any other base structures for forming a circuit may also be used. For example, the substrate may also include glass for display manufacturing.

The outer chamber 120 is arranged to accommodate the inner chamber 110. Unlike the inner chamber 110, the outer chamber 120 is free from concerns about contamination of the substrate and may therefore be made of metal. The outer chamber 120 has a hollow shape having an inner space that accommodates the inner chamber 110.

The gas supply module 130 is configured to supply gas to the inner chamber 110 and the outer chamber 120. The gas supply module 130 has a gas supply device 131 that serves as a gas source. The gas supply device 131 may selectively supply, to the inner chamber 110, reaction gases, such as hydrogen gas (H₂), deuterium gas (D₂), fluorine gas (F₂), ammonia gas (NH₃), chlorine gas (Cl₂), and nitrogen gas (N₂) as a reaction gas for heat treatment. The gas supply device 131 may provide, to the outer chamber 120, a protection gas, such as nitrogen gas or argon gas (Ar) that is an inert gas. The reaction gas and the protection gas may be simply referred to as process gases. The process gases are supplied to the inner chamber 110 or outer chamber 120 via a reaction gas line 133 or a protection gas line 135, respectively. The protection gas supplied to the outer chamber 120 is specifically supplied to a space (protection space) between the outer chamber 120 and the inner chamber 110.

The process gas may be supplied to form a pressure (high pressure) higher than atmospheric pressure, for example, a pressure ranging from several atm to several tens of atm. When the pressure of the reaction gas is a first pressure and the pressure of the protection gas is a second pressure, these pressures may be maintained at a set relationship. For example, the second pressure may be set to be slightly higher than the first pressure. Such a pressure difference provides the advantage of preventing the reaction gas from leaking from the inner chamber 110. The protection space specifically refers to an area within the internal space, excluding the space occupied by the inner chamber 110.

The gas exhaust module 140 is configured to exhaust the process gas. In order to exhaust the reaction gas from the inner chamber 110, an exhaust pipe 141 is connected to an upper portion of the inner chamber 110. Similarly, to exhaust the protection gas from the outer chamber 120, an exhaust pipe 145 communicating with the outer chamber 120 may be provided. Since these exhaust pipes 141 and 145 are integrated into one, the reaction gas is diluted by the protection gas during the exhaust process, and thus, the concentration of the reaction gas is lowered.

The fastening structure of the outer chamber 120 will be described with reference to FIGS. 2 and 3. FIG. 2 is an exploded perspective view illustrating an opened state in which the outer door 125 opens the outer housing 121, in the high-pressure substrate processing apparatus 100 of FIG. 1, and FIG. 3 is a partial cross-sectional view showing a closed state in which the outer door 125 closes the outer housing 121, in the high-pressure substrate processing apparatus 100 of FIG. 2.

Referring to these drawings, the inner chamber 110 includes the inner housing (not illustrated) and the inner door 115. The inner housing forms the processing space that accommodates the substrate W to be processed, and its lower portion may have an open form. The inner door 115 has a form in which the opened lower portion of the inner housing is closed. The inner door 115 may have a trough shape in which it is opened downward overall. As the inner door 115 moves downward, the processing space is opened (opened state, see FIG. 2). As the inner door 115 moves upward, the processing space is closed (closed state, see FIG. 3). The semiconductor substrate W may be loaded onto the wafer boat 113 in the opened state and input into the inner chamber 110.

The outer chamber 120 also includes the outer housing 121 and the outer door 125. The outer housing 121 is sized to accommodate the inner chamber 110. The inner housing (not illustrated) is mounted on the outer housing 121. The outer door 125 may also move to open and close the outer housing 121. The outer door 125 may be connected to the inner door 115 by a support member 127 to support the inner door 115. In this case, the outer door 125 opens and closes the outer housing 121 while moving (elevating) together with the inner door 115.

The high-pressure substrate processing apparatus 100 may further include a fastening module 150 for fastening the outer housing 121 and the outer door 125 in the closed state. Since the inner door 115 is supported on the outer door 125 by the support member 127, the fastening module 150 also ensures that the inner door 115 is in close contact with the inner housing. The fastening module 150 maintains the protection gas at the second pressure within the outer chamber 120. The fastening module 150 also exerts a fastening force to maintain the reaction gas at the first pressure within the inner chamber 110.

The fastening module 150 may specifically include a rotating ring 151, a support protrusion 153, and a locking protrusion 155.

The rotating ring 151 is a ring mounted on the outer housing 121 and is installed to rotate about the center of the outer housing 121. Specifically, a ring-shaped guide groove 123 is formed on an outer surface of the outer housing 121. The rotating ring 151 is inserted into the guide groove 123 and may rotate along a circumference of the outer housing 121 according to its guidance. The force for rotating the rotating ring 151 may be provided from a drive wheel (not illustrated) in contact with the rotating ring 151.

The support protrusion 153 is a protrusion installed on the outer housing 121. As in the present embodiment, the support protrusion 153 may be installed on the outer housing 121 via the rotating ring 151. A plurality of support protrusions 153 may be arranged on an inner circumferential surface of the rotating ring 151.

The locking protrusion 155 is installed on the outer door 125. The locking protrusion 155 is sized to pass between a pair of adjacent support protrusions 153 when the outer door 125 moves in an elevation direction E. The locking protrusion 155 may be provided in the same number as the support protrusion 153.

When the outer door 125 moves upward to be in the closed state, the locking protrusion 155 rotates relative to the support protrusion 153 as the rotating ring 151 rotates. In this case, the locking protrusion 155 is arranged above the support protrusion 153.

The locking protrusion 155 may also move slightly along the elevation direction E between a bottom surface 121′ of the outer housing 121 and a top surface 153′ of the support protrusion 153. The range of movement of the locking protrusion 155 between the bottom surface 121′ and the top surface 153′ is referred to as a gap section.

In the above description, it has been described that the support protrusion 153 rotates relative to the locking protrusion 155 by the rotation of the rotating ring 151. However, the support protrusion 153 may be fixed and the locking protrusion 155 may rotate. To this end, the outer door 125 may rotate in whole or in part.

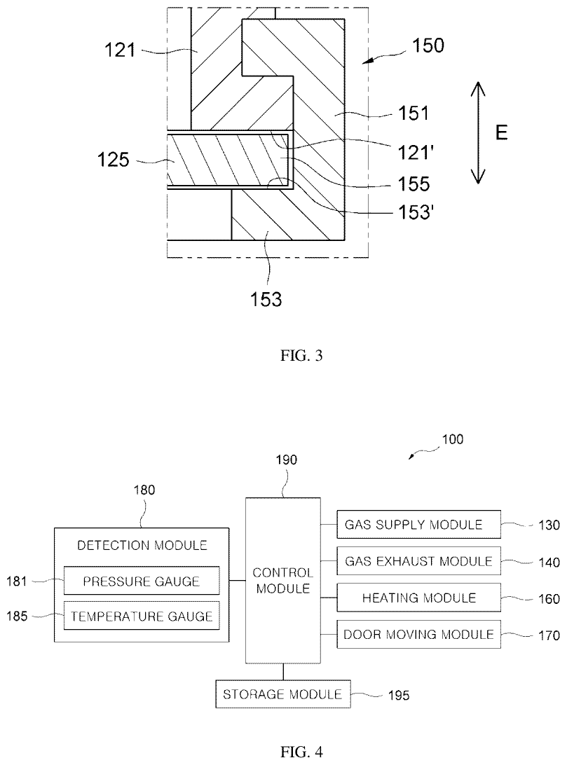

The control configuration of the high-pressure substrate processing apparatus 100 is described with reference to FIG. 4. FIG. 4 is a block diagram illustrating a control configuration of the high-pressure substrate processing apparatus 100 of FIG. 1.

Referring to this drawing (and FIGS. 1 to 3), the high-pressure substrate processing apparatus 100 may further include a heating module 160, a door moving module 170, a detection module 180, a control module 190, and a storage module 195, in addition to the gas supply module 130 and the gas exhaust module 140 described above.

The heating module 160 includes the above-described heater. The heater may be classified as forming a portion of the second chamber 120 or may be classified as a separate heating module 160. The heater is arranged within the second chamber 120 so as to be directed toward the first chamber 110.

The door moving module 170 is configured to move the outer door 125 between the closed state and the opened state. To this end, the door moving module 170 may have an arm (not illustrated) supporting the outer door 125 and a driver (not illustrated) driving the arm. The driver may have a motor (not illustrated) that generates power to drive the arm in the elevation direction E (see FIG. 2). Since the door moving module 170 vertically moves the outer door 125 in the elevation direction E, the door moving module 170 may also be referred to as a door elevating module.

The detection module 180 is a component for detecting the environment of the chambers 110 and 120. The detection module 180 may include a pressure gauge 181 and a temperature gauge 185. The pressure gauge 181 and the temperature gauge 185 may be installed on each chamber 110 and 120.

The control module 190 is a component that controls the gas supply module 130, the gas exhaust module 140, etc. The control module 190 may control the gas supply module 130, etc., based on the detection results of the detection module 180.

The storage module 195 is a component that stores data, programs, etc., that the control module 190 may reference for control purposes.

According to this configuration, the control module 190 may control the operation of the gas supply module 130 based on the pressure of the chambers 110 and 120 obtained through the pressure gauge 181. Depending on the operation of the gas supply module 130, the processing space is filled with the reaction gas at the first pressure. The protection space is filled with the protection gas at the second pressure.

The control module 190 may also control the operation of the gas exhaust module 140 based on the pressure of the chambers 110 and 120 obtained through the pressure gauge 181. Depending on the operation of the gas exhaust module 140, the reaction gas may be exhausted from the processing space. The protection gas may be exhausted from the protection space.

The control module 190 may control the operation of the heating module 160 based on the temperature of the chamber 110 and 120 obtained through the temperature gauge 185. The reaction gas may reach the reaction temperature depending on the operation of the heating module 160.

The control module 190 may also control the door moving module 170 to move the outer door 125 to a specific position within the gap section. As the outer door 125 moves to a specific position within the gap section, the abrasion between the support protrusion 153 and the locking protrusion 155, which may be caused by the sagging of the arm, may be prevented.

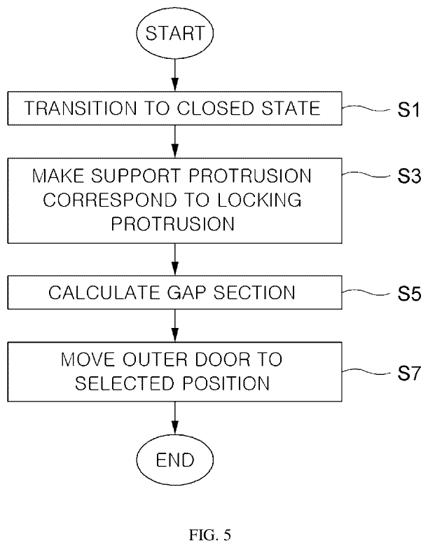

A specific control method for preventing the abrasion between the support protrusion 153 and the locking protrusion 155 will be described with reference to FIGS. 5 to 7.

FIG. 5 is a flowchart for describing an operation of the high-pressure substrate processing apparatus 100 according to another embodiment of the present disclosure.

Referring to this drawing (and FIGS. 1 to 4), the control module 190 controls the door moving module 170 to raise the outer door 125. As a result, the outer door 125, specifically the locking protrusion 155, is stopped between a level corresponding to an upper surface 153′ and a level corresponding to a lower surface 121′ (initial level). The control module 190 may slow down the speed of the door moving module 170 depending on the degree to which the outer door 125 approaches the outer housing 121. The initial level may be a level set during the installation of the door moving module 170. As it is positioned at the initial level, the outer door 125 is placed in the closed state (S1).

The control module 190 operates the rotating ring 151 to rotate the support protrusion 153. As a result, the locking protrusion 155 is positioned partially or fully corresponding to the support protrusion 153 (S3).

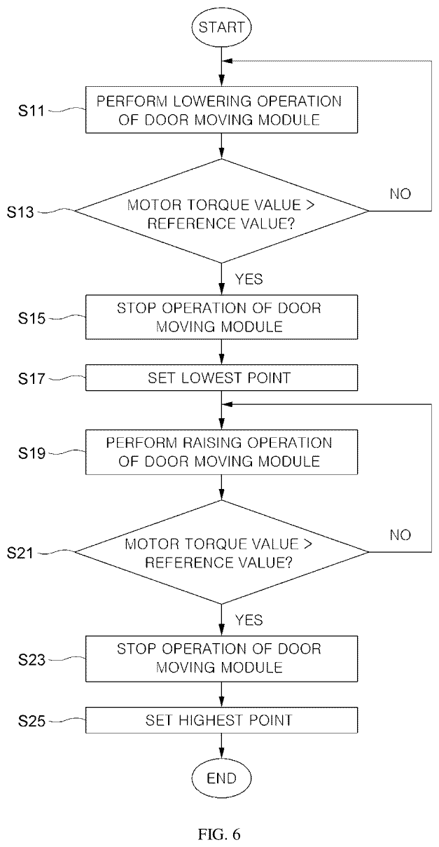

While the locking protrusion 155 is positioned above the support protrusion 153, the control module 190 calculates the gap section (S5). To this end, the control module 190 may operate the door moving module 170 to vertically move the outer door 125. This will be described with reference to FIG. 6.

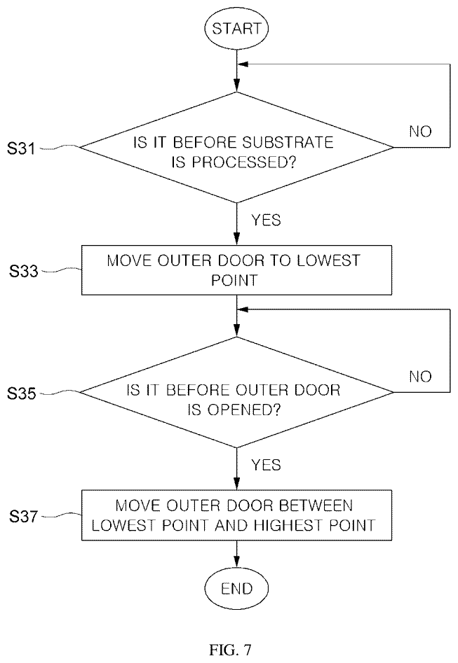

Referring back to FIG. 5, the control module 190 moves the outer door 125 to a selected position within the gap section based on the calculated gap section (S7). By further rotating the rotating ring 151 at the selected position, the locking protrusion 155 may be relatively moved from a position partially corresponding to the support protrusion 153 to a position fully corresponding thereto. The selected position may be selected to prevent the sagging of the outer door 125 and, furthermore, the abrasion with the support protrusion 153. This will be described with reference to FIG. 7.

FIG. 6 is a flowchart for describing in detail one step (S5) of FIG. 5.

Referring further to this drawing, the control module 190 may calculate the gap section based on the operating information of the door moving module 170. The operating information may be a torque value of the motor of the door moving module 170. This is described in detail as follows.

First, the control module 190 operates to lower the door moving module 170 (S11).

As a lowering operation of the door moving module 170 is performed, the outer door 125 moves downward and then stopped by the upper surface 153′ of the support protrusion 153. During the movement of the outer door 125, a higher load is applied to the motor of the door moving module 170. Consequently, the torque value of the motor exceeds a reference value (S13).

The control module 190 stops the lowering operation of the door moving module 170 (S15). The control module 190 sets the level at which the operation of the door moving module 170 is stopped as the lowest point of the gap section (S17).

The control module 190 operates the door moving module 170 to perform a raising operation (S19).

The outer door 125 moves upward and then is stopped by the lower surface 121′ of the outer housing 121. As a result, the torque value of the motor exceeds the reference value (S21).

The control module 190 stops the raising operation of the door moving module 170 (S23) and sets the level at which the door moving module 170 is stopped as the highest point of the gap section (S25).

Alternatively, the control module 190 may first calculate the highest point and then calculate the lowest point. The control module 190 may also calculate only one of the lowest point and the highest point.

FIG. 7 is a flowchart for describing in detail one step (S7) of FIG. 5.

Referring further to this drawing, the control module 190 may control the door moving module 170 to adjust the outer door 125 to a level (adjustment level) different from the initial level, depending on the processing step for the substrate W to be processed. The adjustment level may be one of the selected positions described above. The adjustment level may be the lowest point, the highest point, or a position (level) therebetween. This is described in detail as follows.

First, the control module 190 identifies the processing step for the substrate W to be processed. Before the processing (oxidation, deposition, heat treatment, etc.) for the substrate W begins (S31), the control module 190 moves the outer door 125 to the lowest point (first adjustment level) (S33). Specifically, the control module 190 operates the door moving module 170 to perform the lowering operation so that the locking protrusion 155 is supported on the upper surface 153′ of the support protrusion 153. Even if the process gas is subjected to a pressure higher than atmospheric pressure during the processing, the arm does not deform. Accordingly, the outer door 125 supported by the arm may remain horizontal without sagging to one side. This is because the outer door 125, specifically the locking protrusion 155, is supported by the support protrusion 153.

When the outer door 125 transitions from the closed state to the opened state (S35), the control module 190 moves the outer door 125 to a point (second adjustment level) between the lowest point and the highest point. The second adjustment level may be an intermediate level between the lowest point and the highest point. When the control module 190 calculates only the lowest point or the highest point, the second adjustment level may be the lowest point or a level obtained by adding to or subtracting from the level of the lowest point by a predetermined interval. In order to move to the second adjustment level, the control module 190 should operate the door moving module 170 to perform the raising operation. In this state, the locking protrusion 155 rotates relative to the support protrusion 153 so as to be offset from the support protrusion 153. Even if no sagging of the outer door 125 occurs or the sagging of the outer door 125 occurs, the locking protrusion 155 rotates relative to the support protrusion 153 while being spaced apart from the support protrusion 153, so the generation of particles due to abrasion between the support protrusion 153 and the locking protrusion 155 during the relative rotation may be prevented. The control module 190 now operates the door moving module 170 to perform the lowering operation, so the outer door 125 reaches the opened state.

Although this specification exemplifies the high-pressure processing apparatus 100 with a dual chamber, the present disclosure is not limited thereto. A processing apparatus with a single chamber is also within the scope of the present disclosure. The single chamber includes one housing and one door. The wafer substrate is arranged within the chamber, and the gas for processing the wafer substrate is supplied. The fastening module 150, the control module 190, etc., are also applied to the single chamber.

The configuration of the fastening module 150, etc., may also be applied to a semi-dual chamber, which is an intermediate configuration between the dual chamber and the single chamber. The semi-dual chamber may have two housings (the inner housing and the outer housing) and one door. The two housings may correspond to the inner housing 111 and the outer housing 121 of the above-described embodiment. The two housings may be connected by their own shapes or by intervening with a separate member to form a closed space (corresponding to the protection space). As in the embodiment described above, the substrate may be arranged in the processing space of the inner housing, the reaction gas may be injected, and the protection gas may be injected into the closed space. Unlike the above-described embodiments, the door is not protected by the protection gas.

The door may correspond to the outer door 125 of the above-described embodiments. The door may open and close the inner housing (and the outer housing). The fastening module 150 (and control module 190, etc.) as in the above-described embodiments are applied to the operation between the outer housing and the door.

While the present specification exemplifies a batch-type processing apparatus, the present disclosure is not limited thereto. The present disclosure may also be applied to a single wafer type processing apparatus.

### INDUSTRIAL APPLICABILITY

The present disclosure has industrial applicability in the field of manufacturing the high-pressure substrate processing apparatus.

1. A high-pressure substrate processing apparatus, comprising:
an inner chamber configured to accommodate a substrate to be processed and a reaction gas supplied at a first pressure higher than atmospheric pressure;
an outer chamber including an outer housing for accommodating the inner chamber and an outer door formed to be movable between a closed state in which the outer housing is closed and an opened state in which the outer housing is opened, and configured to accommodate a protection gas supplied at a second pressure set in relation to the first pressure;
a fastening module including a support protrusion installed on the outer housing and a locking protrusion that is installed on the outer door and is positioned to correspond to the support protrusion by relative rotation with respect to the support protrusion in the closed state;
a door moving module configured to move the outer door between the closed state and the opened state; and
a control module configured to calculate a gap section that is a section in which the locking protrusion corresponding to the support protrusion is movable between the outer housing and the support protrusion, and control the door moving module to move the locking protrusion to a selected position within the calculated gap section.

2. The high-pressure substrate processing apparatus of claim 1, wherein the locking protrusion further rotates relative to the support protrusion after being moved to the selected position.

3. The high-pressure substrate processing apparatus of claim 1, wherein the control module calculates at least one of a lowest point and a highest point of the gap section, and
sets, as the selected position, one of the lowest point, the highest point, and a position therebetween.

4. The high-pressure substrate processing apparatus of claim 1, wherein the control module calculates the gap section based on operating information of the door moving module.

5. The high-pressure substrate processing apparatus of claim 4, wherein the door moving module includes a motor that generates power, and
the operating information includes a torque value of the motor.

6. The high-pressure substrate processing apparatus of claim 5, wherein the control module sets, as the lowest point, a point at which the change in the torque value exceeds a reference during downward movement of the outer door, sets, as the highest point, a point at which the change in the torque value exceeds the reference during upward movement of the outer door, and sets a section between the lowest point and the highest point as the gap section.

7. A high-pressure substrate processing apparatus, comprising:
a chamber including a housing configured to accommodate a substrate to be processed and a process gas supplied at a pressure higher than atmospheric pressure, and a door configured to move vertically between a closed state in which the housing is closed and an opened state in which the housing is opened;
a fastening module including a support protrusion that is installed on the housing and a locking protrusion that is installed on the door and is positioned to correspond to the support protrusion at an initial level in the closed state by relative rotation with respect to the support protrusion;
a door elevating module configured to vertically move the door between the closed state and the opened state; and
a control module configured to control the door elevating module so that the locking protrusion corresponding to the support protrusion move vertically to an adjusted level different from the initial level according to a processing step for the substrate to be processed.

8. The high-pressure substrate processing apparatus of claim 7, wherein the control module calculates at least one of a lowest point and a highest point within a vertical movable range while the locking protrusion is positioned to correspond to the support protrusion, and
the adjustment level is set relative to at least one of the lowest point and the highest point.

9. The high-pressure substrate processing apparatus of claim 7, wherein the adjustment level is set to the lowest point before processing the substrate to be processed.

10. The high-pressure substrate processing apparatus of claim 7, wherein the adjustment level is set to a position between the lowest point and the highest point during a transition between the closed state and the opened state.

11. The high-pressure substrate processing apparatus of claim 10, wherein the control module controls the door elevating module to lower the door to the opened state when the locking protrusion rotates relative to the support protrusion after moving the locking protrusion to the adjustment level.

12. The high-pressure substrate processing apparatus of claim 8, wherein the control module calculates at least one of the lowest point and the highest point based on operating information of the door elevating module.

13. The high-pressure substrate processing apparatus of claim 7, wherein the process gas includes a reaction gas containing an active gas and a protection gas containing an inert gas,
the housing includes:
an inner housing configured to accommodate the substrate to be processed and the reaction gas; and
an outer housing accommodating the inner housing and coupled to the inner housing to form a closed space for accommodating the protection gas and the inner housing, and
the door is configured to close the inner housing.
